(19) United States
(12) Patent Application Publication
(10) Pub. No.: US 2026/0229849 A1
(43) Pub. Date: Aug. 6, 2026

(54) SINGLE FREQUENCY LASER ARRAYS

(71) Applicants: Zeyu Zhang, Goleta, CA (US); Minh Tran, Goleta, CA (US); Tin Komljenovic, Goleta, CA (US)

(72) Inventors: Zeyu Zhang, Goleta, CA (US); Minh Tran, Goleta, CA (US); Tin Komljenovic, Goleta, CA (US)

(21) Appl. No.: 19/043,335

(22) Filed: Jan. 31, 2025

(51) Int. Cl. H01S 5/22; H01S 5/06; H01S 5/12; H01S 5/40

(52) U.S. Cl. CPC H01S 5/22; H01S 5/0612; H01S 5/12; H01S 5/4012

(57) ABSTRACT

A device has a substrate attached to a passive waveguide structure which includes a dielectric layer forming a passive waveguide core, and an active waveguide structure, comprising a quantum well layer, attached to a top surface of the passive waveguide structure. The active waveguide structure has first and second mesas of width Wₘ₁ and Wₘ₂ defining a first laser supporting a first optical mode, and a second laser supporting a second optical mode. A grating structure, defined by pitch P, present in at least part of the passive waveguide structure, overlaps with at least an evanescent part of each of the first and second optical modes. The lasing wavelengths of the first and second lasers are in part defined by the first and second mesa widths Wₘ₁ and Wₘ₂ respectively, and by the grating structure pitch P.

### FIELD OF THE INVENTION

The present invention relates to photonic integrated circuits. More specifically, certain embodiments of the invention relate to improved manufacturability and wavelength control of heterogeneously integrated single frequency lasers.

### BACKGROUND OF THE INVENTION

Distributed Feedback (DFB) lasers are a type of semiconductor laser that incorporates a periodic grating structure within the active region of the laser cavity. This grating selectively reflects light at some specific wavelengths while suppressing others, enabling highly stable, single-mode operation.

DFB lasers are extensively used in optical communication systems, where their stable single mode operation and ability to be modulated at high frequency (up to 15 GBps or more) are crucial for transmitting high-speed data over long distances with minimal signal degradation. Their high spectral purity (narrow linewidths plus excellent side-mode suppression) and low sensitivity to temperature variations make them valuable not only in communications, but in precision measurement technologies used in environmental monitoring, medical diagnostics, and other sensing applications.

Despite their many advantages, DFB lasers also have some drawbacks. Their fabrication process is complex and requires precise control, which can increase production costs. The fabrication control can be especially challenging in cases where a set of multiple DFB lasers with precisely controlled wavelengths (not necessarily the same) are to be incorporated into a single photonic integrated circuit (PIC), as process variation can significantly impact yield and cost. A photonic integrated circuit (PIC) is a device that integrates multiple photonic functions and as such is analogous to an electronic integrated circuit. The major difference between the two is that a photonic integrated circuit provides functions for information signals imposed on optical carrier waves.

An example of a complex PIC with multiple (e.g. 4, 8, 16 or more) DFB lasers could be a multi-channel source suitable for wavelength-division-multiplexing (WDM) communication systems where each DFB laser operates at a precise but different wavelength in the ITU grid (with the closest spacing between wavelengths typically corresponding to 50, 100, 200 or 400 GHz). To provide this level of control, the DFB laser design has to provide excellent control of the pitch and strength of the periodic gratings, while, preferably, providing similar gain and output powers from lasers of different wavelengths.

This has been challenging in native indium-phosphide (InP) platforms, resulting in increased costs of such components and PICs. There have been significant advancements in some PIC platforms, including the development of silicon photonics, and more specifically heterogeneous silicon photonics that utilizes more advanced tools with better process control. We use the term “heterogeneous” to describe the approach of bonding two (or more) different materials and then processing them to define the waveguides and other components of interest. As the two (or more) materials are processed on a common wafer using common alignment marks, this removes the need for precise alignment during the bonding and allows for mass fabrication. A problem with heterogeneous silicon photonics is that any gratings formed are strong, for two reasons. One is the large refractive index difference between silicon and the oxide or air filling in the grating spaces. The other is that as the grating is typically positioned at the bonding interface between silicon and a III-V material there is large overlap of the grating with the optical mode resulting in a very large κ (kappa) parameter. κ, also known as the coupling coefficient, measures the strength of interaction between the light wave and the grating. It essentially quantifies how effectively the grating can couple light into different modes or directions. A higher κ value indicates stronger coupling, leading to more significant reflection or transmission changes in the grating structure. It is challenging to control such a grating in mass manufacturing as the etch depth is typically very small (to reduce κ and optimize the κ*length product for stable DFB operation as is known in the art of designing DFB lasers) and must be very precisely controlled; furthermore, controlling the wavelength spacing to precisely match the desired specifications, e.g. the ITU grid, is very challenging, sometimes requiring grating pitch control at a sub-nm level.

There remains a need for a DFB design and PIC platform capable of supporting multiple DFB lasers with precise control of the wavelength that is robust to fabrication variation, in particular by avoiding the use of gratings whose strength is very sensitive to fabrication variation. The present invention is directed to addressing this need by using advanced photonic integration to support the integration of materials with large differences in refractive indices, as described in e.g. U.S. Pat. No. 10,859,764B 2 , employing butt-coupling in combination with a mode-converter. This platform enables the use of relatively low refractive index waveguides (such as silicon-nitride (SiN), silicon-oxynitride (SiNOₓ) lithium-niobate (LiNbO₃₎, tantalum-pentoxide (Ta₂O₅), aluminum-nitride (AlN), alumina (Al₂O₃), doped silicon-dioxide (SiO₂), titanium-dioxide (TiO₂), barium-titanate (BaTiO₃) and/or others) with relatively high refractive index high-performance gain materials realized in III-V (e.g. gallium-nitride (GaN), gallium-arsenide (GaAs), indium-phosphide (InP) and their ternaries and quaternaries).

### BRIEF DESCRIPTION OF THE DRAWINGS

FIG. 1 shows a cross-sectional end-on view of a device according to one embodiment of the present invention, and a corresponding simulated mode profile.

FIG. 2 shows a cross-sectional side view of a device according to some embodiments of the present invention.

FIG. 3 illustrates the impact of geometrical designs on effective index and lasing wavelength, showing both simulated results for the former and measured results for the latter.

FIG. 4 shows three embodiments of the present invention shown in top-down view, and measurements supporting the designs.

FIG. 5 shows a top-down view of an embodiment of the present invention, and a spectral plot illustrating a calibration process for such a design.

FIG. 6 shows three embodiments of photonic integrated circuits according to the present invention.

### DETAILED DESCRIPTION

Described herein are embodiments of heterogeneously integrated single frequency lasers with improved manufacturability and wavelength control.

In the following detailed description, reference is made to the accompanying drawings which form a part hereof, wherein like numerals designate like parts throughout, and in which are shown by way of illustration embodiments in which the subject matter of the present disclosure may be practiced. It is to be understood that other embodiments may be utilized, and structural or logical changes may be made without departing from the scope of the present disclosure. Therefore, the following detailed description is not to be taken in a limiting sense, and the scope of embodiments is defined by the appended claims and their equivalents.

The description may use perspective-based descriptions such as top/bottom, in/out, over/under, and the like. Such descriptions are merely used to facilitate the discussion and are not intended to restrict the application of embodiments described herein to any particular orientation. The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The term “coupled with,” along with its derivatives, may be used herein. “Coupled” may mean one or more of the following. “Coupled” may mean that two or more elements are in direct physical, electrical, or optical contact. However, “coupled” may also mean that two or more elements indirectly contact each other, but yet still cooperate or interact with each other, and may mean that one or more other elements are coupled or connected between the elements that are said to be coupled with each other. The term “directly coupled” means that two or more elements are in direct contact in at least part of their surfaces. The term “butt-coupled” is used herein in its normal sense of meaning an “end-on” or axial coupling, where there is minimal, or zero axial offset between the elements in question. The axial offset may be, for example, slightly greater than zero in cases where a thin intervening layer of some sort is formed between the elements, such as e.g. thin coating layer typically used to provide high-reflectivity or anti-reflectivity functionality. It should be noted that the axes of two waveguide structures or elements need not be colinear for them to be accurately described as being butt-coupled. In other words, the interface between the elements need not be perpendicular to either axis in the case of e.g. an angled interface. No adiabatic transformation occurs between butt-coupled structures.

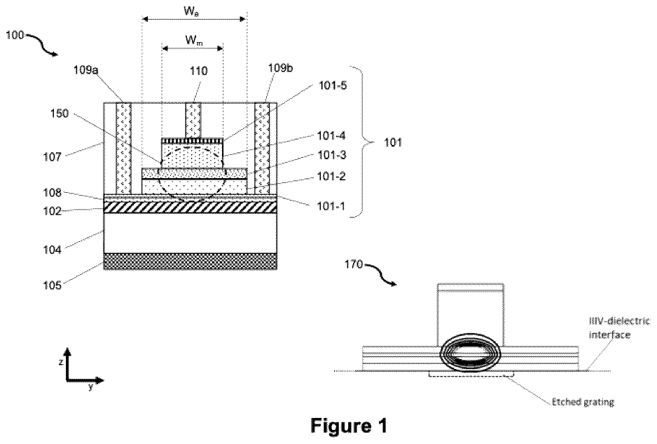

FIG. 1 is a schematic cross-section end-on view of a heterogeneously integrated photonic device 100 according to present invention. The illustrative cross-section includes a substrate 105 that can be any suitable substrate for semiconductor and dielectric processing, such as Si, InP, GaAs, quartz, sapphire, glass, GaN, silicon-on-insulator or other materials known in the art. In the shown embodiment, a layer 104 of a second material is deposited, grown, transferred, bonded or otherwise attached to the top surface of substrate 105 using techniques known in the field. The main purpose of layer 104 is to provide optical cladding for material layer 102 (to be described below), if necessary to form an optical waveguide. Optical waveguides are commonly realized by placing a higher refractive index core between two lower refractive index layers to confine the optical wave. In some embodiments, layer 104 is omitted and substrate 105 itself serves as a cladding for the core layer 102.

Layer 102 is deposited, grown, transferred, bonded or otherwise attached to the top of layer 104 if present, and/or to the top of substrate 105, using techniques known in the field. The refractive index of layer 102 is higher than the refractive index of layer 104 if present, or, if layer 104 is not present, the refractive index of layer 102 is higher than the refractive index of substrate 105. In one embodiment, the material of layer 102 may include, but is not limited to, one or more of SiN, SiNOₓ, TiO₂, Ta₂O₅, (doped) SiO₂, LiNbO_{3,} Al₂O₃, BaTiO₃ and AlN, which are commonly known as dielectric layers. In some embodiments, other common dielectric materials may be used for layer 102. Either or both layers 104 and 102 can be patterned, etched, or redeposited to tailor their functionality (by defining waveguides, splitters, couplers, gratings and other passive components) as is common in the art (not shown in FIG. 1, but as would be visible in an x-y cut). Layer 102 corresponds to what is called a passive waveguide core, or passive waveguide core layer in the remaining part of the disclosure, including the claims. The combination of a passive waveguide core layer with layers providing cladding functionality, and an optional planarization layer described below, forms the passive waveguide or passive waveguide structure in the remaining part of the disclosure, including the claims.

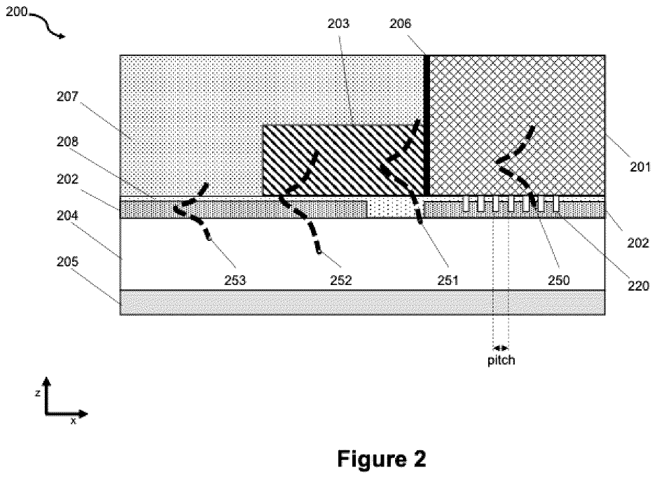

Layer 108, whose refractive index is lower than the refractive index of layer 102, overlays layer 102 and underlays layers 101 and 203 (the latter is not visible in the y-z plane shown in FIG. 1 but is described below with reference to FIG. 2). Layer 108 serves to planarize the patterned surface of layer 102 as further illustrated in FIG. 2. In some embodiments, the planarity of the top surface of layer 108 is provided by chemical mechanical polishing (CMP) or other etching, chemical and/or mechanical polishing methods. In other embodiments, the planarity is provided by the intrinsic nature of the method by which layer 108 is deposited, for example if the material of layer 108 is a spin-on glass, polymer, photoresist or other suitable material. The planarization may be controlled to leave a layer of desired, typically very low, thickness on top of the layer 102 (as shown in FIG. 1), or to remove all material above the level of the top surface of the layer 102 (not shown). In cases where layer 108 is left on top of layer 102, the target thicknesses are in the range of a few nm to several hundreds of nm, with actual thickness, due to planarization process non-uniformities, being between zero and several hundreds of nanometers larger than the target thickness. In some embodiments, a spin-on material is used for planarization, and is then etched back, potentially resulting in improved thickness uniformity across the wafer compared to typical CMP processes. The top surface of layer 108 is typically characterized by low surface roughness which makes it suitable for bonding. In some cases, the roughness is <5 nm RMS, in others it is <1 nm RMS. It is generally known that bonding yield is improved as surface roughness is reduced. A good CMP process can produce a surface roughness of 0.5 nm RMS or lower (better). Layer 108 corresponds to what is called a planarization layer in the remaining part of the disclosure, including the claims.

Layer 101 is bonded on top of at least part of the corresponding passive waveguide or passive waveguide structure (108, 102) top surface. The bonding can be direct molecular bonding, or additional materials can be used to facilitate bonding such as e.g., polymer films as is known in the art. The bonding material, if used, has to have reasonably low losses at the wavelength of operation, because the optical mode 150, at least in the evanescent field, has overlap with layer 108 and/or layer 102. Layer 101 comprises at least one of GaN, GaAs and InP, and their ternary and quaternary compositions. Layer 101 in some embodiments, including the one shown in FIG. 1, is multilayered, comprising sublayers providing both optical and electrical confinement as well as electrical contacts, as is known in the art for active devices. In the embodiment shown in FIG. 1, layer 101 comprises five distinct sublayers 101-1, 101-2, 101-3, 101-4 and 101-5, all of which can comprise additional sublayers. Sublayers of layer 101 in some embodiments provide vertical confinement (up/down in FIG. 1 or along the z-axis), while lateral confinement (left/right in FIG. 1 or along the y-axis) is provided by at least one z-axis etch. In the embodiment shown, one etch defines mesa width (Wₘ) and provides lateral confinement of the optical mode, while another etch defines active region width (Wₐ) that serves to allow the contact layer 101-1 to be accessed for metal deposition (described in more detail below) and provide either p-type or n-type electrical contacts (though not both). Layer 101 corresponds to what is called active layer, active waveguide, or active waveguide structure in the remaining part of the disclosure, including the claims.

Sublayer 101-1 comprises a highly doped contact layer. Doping is the process of intentionally introducing impurities into an intrinsic (pure) semiconductor to modify its electrical properties. This is done to enhance the semiconductor's conductivity. In some embodiments it is a n-doped contact layer, and in other embodiments it is a p-doped contact layer. In some embodiments, the thickness of the contact layer is between 50 nm and 500 nm. The doping is typically greater or equal to 1e18¹ atoms/cm³ to provide good contacts, but in some embodiments can be lower. The doping can be constant, or piece-wise constant, or graded or a combination of any or all of these. In some embodiments, typically when the ¹ For simplicity and convenience, units of atoms/cm³ are assumed for doping levels in the remainder of the document, but will not be shown explicitly. contact layer thickness is >150 nm, doping can be higher at the top (towards the contact), and lower at the bottom (toward the bonded interface with 108 or 102). This can result in reduced internal loss. Electrical contacts 109a and 109b are laterally offset from the optical mode 150, so they do not contribute significantly to the optical loss. Sublayer 101-1, in some embodiments, also comprises a superlattice realized by at least two thin layers with different properties. The superlattice can serve to prevent the propagation of dislocations, or otherwise facilitate more robust laser performance. In some embodiments, a low strain is introduced into the superlattice layer to improve the dislocation filtering effect. The typical thickness of each superlattice layer is <10 nm but can be as thick as 50 nm.

Sublayers 101-2 and 101-3 define what is called the active region width (Wa). In some embodiments, the active width can be the same as the mesa width (Wm) defined by patterned sublayers 101-4 and 101-5 as described below, but in the embodiment shown, active width Wa is larger than mesa width Wm, with a goal of reducing the overlap of optical mode 150 with the etched sidewalls (left and right) of the active region 101-3.

Active region 101-3 comprises quantum well and/or quantum dot layers with optional separate-confinement heterostructure (SCH) layer(s). In the remainder of this disclosure, including the claims, the term “quantum well” is used for simplicity to include quantum dot layers, quantum well layers and/or combinations of them.

Optional sublayer 101-2 can comprise what is commonly known as cladding and/or waveguide layers. The doping of a cladding layer (n-type or p-type) matches the doping type of the 101-1 highly doped contact layer. The layers of sublayer 101-2 comprise optically transparent materials (characterized by low material loss) at the wavelength of operation with background doping that is typically smaller than in the contact region. Doping can be constant, piece-wise constant, graded and/or a combination of some or all.

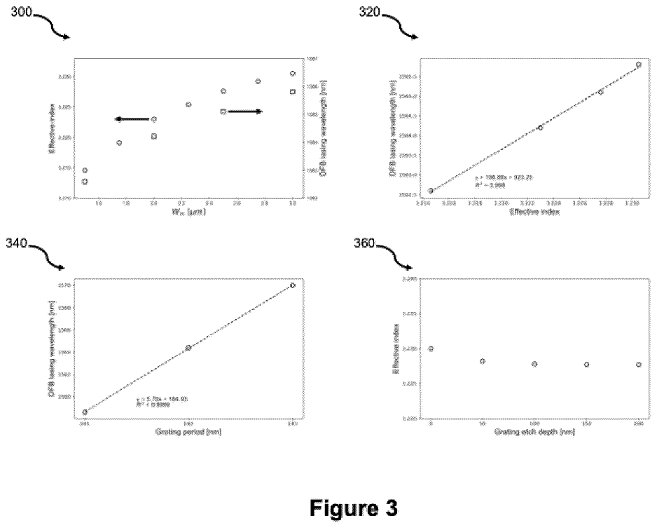

Sublayer 101-4 is the second cladding layer, with opposite polarity (p-type or n-type) from sublayers 101-1 and 101-2 (if present). The cladding layer 101-4 serves to reduce internal loss by controlling the overlap between the optical mode 150 and metal 110 and between the optical mode 150 and sublayer 101-5, providing second contact functionality described below. The width of sublayer 101-4 defines mesa width (Wm) and can be used to control the effective index of the mode as will be explained in more detail with the help of FIG. 3. By controlling the effective index, we can also control the lasing wavelength of a DFB laser.

Sublayer 101-4 can comprise additional layers such as bandgap smoothing layers, etch stop layers, graded layers, etc. to provide improved performance or facilitate more robust fabrication as is known in the art of semiconductor device design and fabrication. Sublayer 101-4 is doped, with doping levels typically between 1e16 and 2e18, but can be outside of this range as well. The thickness of sublayer 101-4 varies depending on the wavelength of operation, and the refractive index difference between the sublayers 101-3 and 101-4. In some embodiments, the thickness of the sublayer 101-4 is larger than 400 nm. The doping and thickness optimization achieves a balance between keeping series resistance low while also keeping the optical loss acceptably low, noting that p-doped materials typically have higher optical loss than the n-doped materials. The doping of sublayer 101-4 can be constant, piece-wise constant, graded and/or a combination of some or all. Both the contact resistance optimization and the optical loss optimization can be carried out with commercial numerical solvers or other simulation/calculation means including analytical expressions and approximation formulas.

Sublayer 101-5 is the second contact layer whose polarity is opposite to that of sublayer 101-1. In some embodiments sublayer 101-5 comprises a highly doped layer with doping >5e18. In yet other embodiments the doping is even higher, reaching 1e19 or more. Higher (optical) loss layers can be used as contact layers in 101-5, as the relatively thick cladding 101-4 keeps the overlap of the mode 150 and sublayer 101-5 small. In some embodiments the thickness of the contact layer is between 50 nm and 250 nm.

Metal contacts 109a, 109b and 110 provide ohmic contacts to respective semiconductor contact layers (as a part of sublayers 101-1 and 101-5). All contacts can be connected to pad metal (not shown) through vias to facilitate efficient current and/or voltage control of the active device.

The upper cladding layer 107 can be any suitable material including, but not limited to, a polymer, SiO₂, SiN, SiNOₓ etc. In some embodiments, the same material is used for layer 107 and layer 108. In some embodiments (not shown), layer 107 cladding functionality can be provided with multiple depositions and multiple materials, e.g. to both provide cladding and passivation of the active device.

View 170 is a simulated illustration of the laser cross-section and the fundamental mode, clearly indicating the interface between the III-V (active) layer and the underlying dielectric layers (planarization layer, passive waveguide core layer), and the position of the grating etched into those layers, where only the evanescent field of the optical mode “sees” the grating. This enables low κ kappa gratings to support robust laser designs as will be described below with the help of FIG. 3.

FIG. 2 is a schematic cross-section side view of an integrated photonic device 200 utilizing butt-coupling and mode conversion for efficient coupling between dissimilar materials according to some embodiments of present invention. Functional layers 201 to 208 (unless explicitly defined differently) correspond to functional layers 101 to 108 as described in relation to FIG. 1.

Optional planarization layer 208, whose refractive index is lower than the refractive index of layer 202, overlays layer 202 and underlays layers 201 and 203 (described in more detail below).

Layer 201 is bonded onto a top surface of at least part of the corresponding passive waveguide structure, including layer 202, and optional planarization layer 208. Layer 201 makes up what is commonly called an active layer and comprises multiple sublayers (101-1, 101-2, 101-3, 101-4 and 101-5 as described with the help of FIG. 1). The optical mode 250 (which is dominantly guided inside the active layer) has an evanescent tail that extends to layers 202/208. Periodic structures, such as etched air pockets 220, in 202/208 can form a grating and provide optical feedback to realize distributed feedback (DFB) lasers or similar, where such structures are typically defined in terms of a pitch corresponding to the spacing between the teeth of the grating. In other embodiments, the grating is not realized simply by forming the air pockets, but by depositing a different material, with different refractive index, inside the pockets. Further optimization of the performance of the laser can be obtained by introducing defects to the grating (not shown) to provide a quarter-wavelength shift, or multiple shift sections as is known in the art of designing high performance DFB lasers. Such shifts can improve laser stability, and also reduce the impacts of spatial hole burning due to the formation of a standing wave inside the active region.

Efficient coupling between optical mode 250, predominantly residing in active waveguide structure 201, and optical mode 253, predominantly residing in the passive waveguide structure for which layer 202 provides the core, is facilitated by layer 203, and, in cases where layer 206 is present, by layer 206. Optional layer 206 primarily serves as either an anti-reflective or a highly reflective coating at the interface between layer 201 and layer 203. In some embodiments, it can also serve to passivate the facet and support higher output powers. Layer 203, butt coupled to active waveguide structure 201, serves as an intermediate waveguide that in some embodiments accepts the profile (depicted by line 250) of an optical mode supported by the waveguide for which layer 201 provides the core, captures it efficiently as mode profile 251, and gradually transfers it to mode profile 252, and finally to mode profile 253. Mode profile 253 is efficiently coupled into the waveguide for which layer 202 provides the core.

The use of intermediate layer 203 significantly improves efficient the optical transfer between the very high refractive index materials providing optical gain (201), and the relatively low refractive index materials in layer 202, without requiring prohibitively narrow tapers (to directly match the mode refractive indices between the high and low refractive index waveguides) that are challenging to fabricate.

Differences between the optical modes supported by waveguides in layers 201 and 202 respectively may or may not be obvious by observation of the mode profiles, but mode shape overlaps less than 100%, along with non-zero vertical offsets (in FIG. 2) between modes 250 and 253 could (in the absence of intermediate layer 203) result in significant optical loss. In some cases, losses of up to 2 dB may be considered acceptable, but losses greater than that might not be. In other cases, a 5 dB loss level may be the criterion chosen for acceptability. The function of layer 203 is to keep optical coupling losses due to imperfect mode overlap and vertical offset (between modes 250 and 253) below whatever is determined to be an acceptable level in a given application.

In some embodiments, layer 208 is not present and both layers 201 and 203 are positioned on top of a patterned layer 202, in the case of 201 by bonding, and in the case of 203 by various deposition methods (not shown). In such embodiments, there is no planarization step, and gratings are defined solely in layer 202.

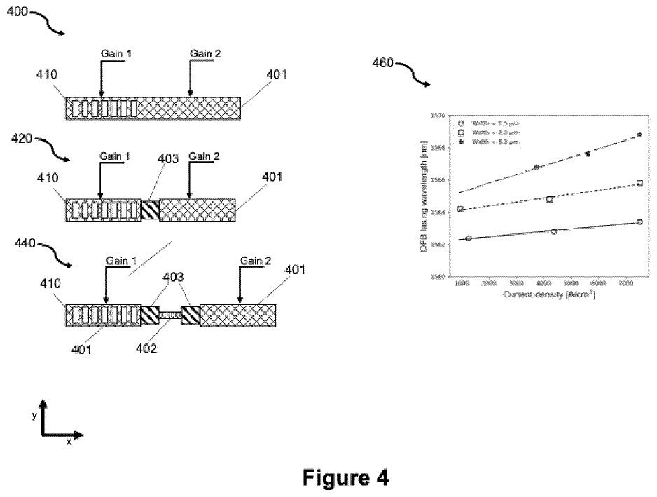

FIG. 3 shows some illustrative simulation and characterization results related to designing a single-frequency heterogeneous laser. The lasing wavelength is affected by grating pitch and the effective index of the optical mode, and therefore can be controlled by adjustments to either or a combination of both. In this photonic platform, the effective index of the optical mode, is predominantly defined by III-V layers (active layers) as they have much higher refractive index than other layers (passive layers), used for cladding or planarization, so the majority of the optical mode resides inside the active layers. The effective index of the mode can be controlled by the mesa width (Wm) and also by current injection (both carrier and thermal effects) as will be described below and with the help of FIG. 4.

View 300 shows the impact of the mesa width (Wm) on the effective index of the optical mode (circles), as numerically calculated, and on the corresponding DFB lasing wavelength (rectangles), as experimentally characterized from illustrative test structures. The grating pitch, in the illustrative case of results shown in view 300 is held constant at 242 nm, and the grating depth, defined by etch depth through the combination of passive waveguide core and planarization layers, is >100 nm. View 300 shows that the lasing wavelengths of DFBs with gratings of the same pitch can be different. The effect of mesa width on effective index is non-linear, and typical mesa widths range from ~0.25 μm (impacted by processing limitation, including metallization, vias, misalignment, etc.) to 8 μm or more with effective index change saturating for very wide mesas.

View 320 shows a very good linear fit between simulated effective index and the corresponding measured DFB lasing wavelength, suggesting that our models capture the experimental results well. In other words, DFB lasing wavelengths can be precisely controlled by changing the mesa width to correspondingly change the effective index.

View 340 shows the ability for coarse DFB wavelength control by adjusting the pitch of the grating. In this particular case, the change of the grating pitch by one nanometer corresponds to 5.7 nm of wavelength change. This coarse change can be too large for some systems (e.g. 50 GHz ITU grid), so use of mesa width wavelength control is necessary to provide more precise control. Nevertheless, pitch control can help DFBs cover very broad wavelength ranges, like the combination of S+C+L bands, for example.

View 360 shows that this design of DFB laser, and more specifically the grating, is very robust in terms of fabrication tolerance, as the effective index has very low dependence on the etch grating depth (inside layers 102/108). This contrasts well with e.g. heterogeneous III-V silicon devices. This is due to the fact that the grating is only interacting with the evanescent field of the optical mode. In most cases, etching gratings deeper than 100 nm results in saturation of the impact of depth on the optical mode.

FIG. 4 shows three additional embodiments of the DFB laser structure with improved wavelength control and corresponding illustrative measured results from test structures. As stated above, another means to control the wavelength of the DFB laser is by current injection (both carrier and thermal induced refractive index change), but this also results in a change of the output power. To de-couple the wavelength control and output power, in some embodiments the active layer structure is separated into at least two regions. One region has the grating and serves as a seed DFB laser that can be tuned with current injection, while the other region acts as an amplifier and can provide power control that is separate from the wavelength control.

View 400 shows an embodiment where active layer (401) is continuous, but only part of the layer has grating 410. There are at least two electrical connections (Gain 1 and Gain 2), where Gain 1 predominantly pumps the grating region (and provides wavelength control), while Gain 2 predominantly pumps the amplifier section (and provides output power control). Various optimizations, e.g. breaking of the contact metal, implants, and/or etches can be utilized to provide additional isolation between the two electrical connections to improve the ability to control wavelength and power.

View 420 shows another embodiment of the DFB +amplifier configuration, but in this case active layer 401 is split into two parts (where only one has the grating 410) that are optically coupled via the intermediate element 403 (corresponding to layer 203 as described above with respect to FIG. 2). Interfaces between 401 and 403 can be angled (not shown) to suppress reflections and improve performance.

View 440 shows another embodiment of the DFB +amplifier configuration, but in this case two parts of the active layer are optically coupled via intermediate elements 403 and waveguides realized with passive waveguide core layer 402 (corresponding to layer 202 as described above with respect to FIG. 2). Interfaces between 401, 402, and/or 403 can be angled (not shown) to suppress reflections and improve performance. The grating 410 is defined only in one part of the active layer 401.

View 460 shows the impact of injected current density on the DFB lasing wavelength for three different mesa widths (Wm) of identical length lasers with identical grating pitch. Here we plot the current density (as laser size is different due to different width), but we could also plot total injected current with identical wavelength changes. In this case, the results would be relatively offset along the x-axis. These measurements clearly show that significant wavelength control is achievable by controlling the laser injection current.

Yet another way to control the wavelength of DFB laser is to implement a local heater close to the active region (not shown)-in this way the wavelength of emission can be controlled by thermal tuning of the mode refractive index without directly impacting the pump current of the laser (not shown). As the temperature increases, the output power of the laser generally decreases, so it is still beneficial to have an amplifier to provide better power control.

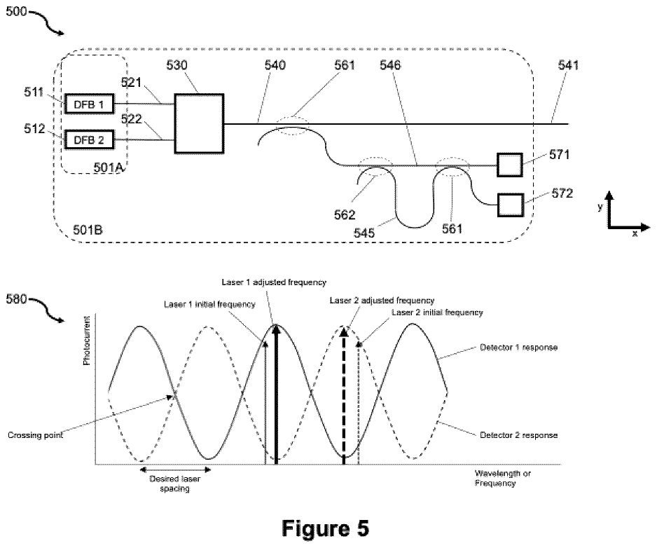

FIG. 5 shows one embodiment of a subset of embodiments of the present invention in which two lasers are fabricated utilizing the above optimization techniques for precise wavelength control, and whose wavelengths or frequencies of operation can be further controlled using on-chip wavemeters or similar devices to hit the required spacing and/or wavelengths with required precision, potentially exceeding fabrication non-uniformities. This embodiment may also utilize current tuning and/or thermal tuning as explained with the help of FIG. 4.

The embodiment shown in view 500 comprises two DFB lasers 511 and 512 that are coupled via waveguides 521 and 522 to a combiner element 530. In other embodiments, the number of lasers sharing a common substrate and fabricated as described above can be larger than two. Combiner element 530 receives inputs from the lasers via waveguides (521 and 522) and combines them into single output 540 with low insertion loss. Examples of combiner element 530 include various couplers (directional, adiabatic, multi-mode interference, inverse design), ring-resonator based structures, arrayed waveguide gratings, echelle gratings, periodic structures and/or others. The DFB lasers 511 and 512, in some embodiments, can be structures with at least two electrical connections to provide both wavelength and power control as described with the help of FIG. 4 and/or can include local heaters to provide thermal tuning of the wavelength.

A small part (typically around 1%, but it could be larger or smaller) of the output 540 can be tapped via coupler 561 and routed to an unbalanced Mach-Zehnder (UMZI) element formed by two couplers 561 and 562 and two waveguide arms 545 and 546 that are characterized by different lengths. In the embodiment shown, the two UMZI outputs are fed into two corresponding photodetectors 571 and 572, but in other embodiments only one output may be fed into a photodetector. The length difference between waveguide arms 545 and 546 can be designed such that for a target (desired) wavelength spacing of S for the two laser outputs, the response of the UMZI has a periodicity substantially corresponding to either N*S or (1/N)*S where N is an integer. The un-tapped part of the output 540 propagates towards the PIC output 541.

To precisely control the wavelengths of the DFBs, we can turn DFBs on sequentially (only one active at each time during calibration) and monitor their response on the UMZI as they are tuned by current injection. To hit the exact spacing as defined by UMZI, we can tune each laser to hit either maximum, minimum or cross location (if two photodetectors are used) in the UMZI response shown in view 580. In this case, we assume that our process control is sufficient to roughly (initially) hit target spacing (with error being <50% of the UMZI periodicity), and then each laser can easily be “snapped” with the desired precision to hit the target wavelength using the UMZI and the photodetectors. In some embodiments, the UMZI itself can be made tunable (not shown) by implementing e.g. thermal heaters. It is clear that this approach can easily be scaled to more than two DFB lasers. In other embodiments, not shown, elements other than UMZI's can be utilized to align the lasers to a desired wavelength separation. Examples include ring-resonators, or external references such as Fabry-Perot cavities and/or gas references. In yet other embodiments, multiple UMZIs with different periodicity can be utilized for control of the lasers over a wider range and/or for control of lasers produced with inferior process control, where initial laser wavelength spacings might be larger than 50% of the single UZMI periodicity).

For some laser array applications, PICs can be fabricated that include only the laser sources themselves without any of other optical components such as waveguide couplers, wavelength references, photodetectors etc. In FIG. 5, dashed outline 501A indicates the boundary of a minimal PIC device embodiment of the present invention, on which only the two lasers 511 and 512 are fabricated, while dashed outline 501B indicates the boundary of a fully integrated embodiment, where a single PIC would include not only the lasers but all the downstream passive and active elements in place to provide a useful optical output at 541. Intermediary cases (not shown) are also possible, of course, in which some but not all of such downstream elements would be integrated onto a single PIC substrate.

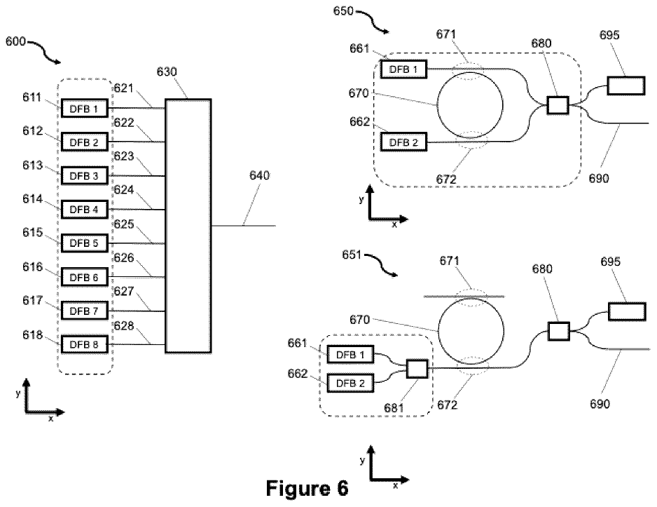

FIG. 6 shows three embodiments of the PIC according to the present invention, where PIC functionality requires precise control of the wavelength of each laser. View 600 shows a first embodiment, a WDM source comprising 8 DFB lasers (611-618) that are coupled via waveguides 621-628 respectively to a combiner element 630. Combiner element 630, similar to combiner 530 as described with the help of FIG. 5, combines all inputs into single output 640 with low insertion loss. Each of the lasers implements precise wavelength control as described with the help of FIGS. 1-5 and can include UMZI based elements (not shown) or other references to hit its desired value, matching a value on the ITU or similar grid, separated from those of the other lasers by a corresponding grid spacing.

Views 650 and 651 show two illustrative embodiments of an RF generator, each utilizing two DFB lasers 661 and 662 that are self-injection locked to the same resonator 670.

The embodiment shown in view 650 utilizes two tap-couplers 671 and 672 to separately couple the two lasers into resonator 670, which then delivers its two outputs to combiner 680, which in turn sends one combined optical output to an external element such as a fiber via waveguide 690, and the other combined output to high speed photodetector 695, where RF signals may be generated.

The embodiment shown in view 651 first combines the two lasers using combiner 681 and then couples the combined laser output into resonator 670 using a single tap-coupler 672. Resonator 670 then delivers its two outputs to splitter 680, which in turn sends one combined optical output to an external element such as a fiber via waveguide 690, and the other combined output to high speed photodetector 695, where RF signals may be generated. Optional coupler 671 can be used to provide an alternative output for the lasers, that is typically characterized with lower output power, but also lower noise.

Lasers 661 and 662 implement precise wavelength control as described above with respect to the embodiments shown in FIGS. 1-5 and can utilize the ring-resonator as a reference for alignment but can also include other references based on UMZI or similar structures (not shown). The precise control is necessary as it defines the output RF signal frequency that is determined by the difference in the optical frequencies between the two lasers.

As discussed above with respect to the embodiments shown in FIG. 5, the degree of integration of the optical components involved in the FIG. 6 embodiments on a shared PIC substrate can vary over a wide range. The dashed outline in view 600 shows the PIC boundary for a minimal case, including only the array of 8 lasers; the dashed outline in view 650 shows the PIC boundary for a more fully integrated case, where the ring resonator and associated couplers and splitter components are included along with the 2 lasers; and the dashed outline in view 651 shows an intermediate case. These are just examples, with more or less integrated PIC boundaries being feasible for any of the arrangements of components shown.

It is to be understood that these illustrative embodiments discussed above teach just some examples of heterogeneously integrated single frequency lasers with improved manufacturability and wavelength control. Furthermore, such lasers can be combined with multiple other components to provide additional functionality or better performance such as various filtering elements, amplifiers, monitor photodiodes, modulators and/or other photonic components.

Embodiments of the present invention offer many benefits. The integration platform enables scalable manufacturing of PICs with single-frequency lasers made from multiple materials providing improved yield, manufacturability and cost.

This present invention utilizes a process flow consisting typically of wafer-bonding of a piece of compound semiconductor material on a carrier wafer with dielectric waveguides (as is described with the help of FIGS. 1 and 2) and subsequent semiconductor fabrication processes as are known in the art. It enables an accurate definition of optical alignment between active and passive waveguides typically via a lithography step, removing the need for precise physical alignment. Such lithography-based alignment allows for scalable manufacturing using wafer scale techniques.

It is to be understood that optical coupling between modes in active and passive layers is reciprocal, so that, taking FIG. 2 as exemplary, the structure can be configured to facilitate light transmission from region 201 to region 202 (e.g. DFB laser to passive waveguide), but it could also facilitate transmission in the reverse direction, from region 202 to region 201 (e.g. optical signal in passive waveguide to optical amplifier). It is to be understood that multiple such transitions with no limitation in their number or orientation can be realized on a single suitably configured PIC.

It should be appreciated that embodiments of the present invention derive significant benefits due to the use of an advanced material platform, which allows for the creation of low strength gratings, defined in a dielectric material with refractive index much lower than that of the III-V material. First, the grating strength will be inherently low due to the index contrast between the grating “teeth” and the oxide or air-filled gaps between them being low. Second, because the optical mode predominantly resides in the III-V material rather than in the low index dielectric, there is much less mode overlap with the grating. The combination of both factors results in a grating of low κ. This enables much simplified control of the gratings, significantly improving the manufacturability, yield, and consequently lowering the cost of such PICs.

As described above, other key design features of the embodiments illustrated in FIGS. 1-6 allow for fine control of the output wavelength by adjusting (1) the grating pitch in the lower refractive index material and (2) the width of the laser mesa which confines the mode in the higher-refractive index (III-V) material. This allows for precise control of output frequencies of individual lasers and of the array of frequencies output from a corresponding array of lasers fabricated on the same PIC, of particular value in conforming to communication grid frequency standards.

Embodiments of the optical devices described herein may be incorporated into various other devices and systems including, but not limited to, various computing and/or consumer electronic devices/appliances, communication systems, computational systems, medical devices, sensors and sensing systems.

It is to be understood that the disclosure teaches just few examples of the illustrative embodiment and that many variations of the invention can easily be devised by those skilled in the art after reading this disclosure and that the scope of the present invention is to be determined by the following claims.

1. A device comprising:
a passive waveguide structure attached to a substrate, the passive waveguide structure comprising a dielectric layer forming a passive waveguide core; and
an active waveguide structure attached to a top surface of the passive waveguide structure, the active waveguide structure comprising a quantum well layer;
wherein the active waveguide structure has a first mesa of width Wₘ₁ defining a first laser supporting a first optical mode, and a second mesa of width Wₘ₂ defining a second laser supporting a second optical mode;
wherein a grating structure, defined by pitch P, present in the passive waveguide structure, overlaps with at least an evanescent part of each of the first and second optical modes; and
wherein the lasing wavelengths of the first and second lasers are in part defined by the first and second mesa widths Wₘ₁ and Wₘ₂ respectively, and by the grating structure pitch P.

2. The device of claim 1,
wherein the grating structure is present in the dielectric layer forming the passive waveguide core.

3. The device of claim 1,
wherein the passive waveguide structure additionally comprises a planarization layer; and
wherein the grating structure is present in the planarization layer.

4. The device of claim 1,
wherein the passive waveguide structure additionally comprises a planarization layer; and
wherein a first part of the grating structure is present in the dielectric layer forming the passive waveguide core and a second part of the grating structure is present in the planarization layer.

5. The device of claim 1,
wherein each of the mesa widths, Wₘ₁ and Wₘ₂, is larger than 0.25 μm and smaller than 8 μm.

6. The device of claim 1,
wherein each of the first and second lasers has a corresponding amplifier defined in the active waveguide structure, such that each laser and corresponding amplifier have a corresponding set of dedicated electrical contacts to provide current injection, and in combination provide a corresponding output power;
wherein the lasing wavelength of each laser can be in part controlled by adjustment of a current injected into that laser; and
wherein the output power from each combination of laser and corresponding amplifier can be in part controlled by adjustment of a current injected into that amplifier.

7. The device of claim 1,
wherein each of the lasers defined in the active waveguide structure has a corresponding heater element; and
wherein the lasing wavelength of each laser can be in part controlled by the corresponding heater element, and an output power output from that laser can be in part controlled by a current injected into that laser.

8. A photonic integrated circuit comprising:
the device of claim 6;
a combiner element, receiving the output power from each combination of laser and corresponding amplifier, and providing a combined output power;
an unbalanced Mach-Zehnder (UMZI) element, receiving a part (x %) of the combined optical power, the response periodicity of the UMZI being substantially equal to either N*S or (1/N)*S, where N is an integer and S is a target wavelength spacing of the lasers; and
a photodetector, coupled to a UMZI output;
wherein the currents injected into the lasers are operated such that each of the lasing wavelengths is aligned to a corresponding one of a UMZI maximum, minimum, and crossing point.

9. The photonic integrated circuit of claim 8,
where x is between 0.01 and 50.

10. The photonic integrated circuit of claim 8,
where the target wavelength spacing S corresponds to a target frequency spacing between 10 GHz and 1600 GHz.

11. A photonic integrated circuit comprising:
the device of claim 7;
a combiner element, receiving the output power from each combination of laser and corresponding heater element, and providing a combined output power;
an unbalanced Mach-Zehnder (UMZI) element, receiving a part (x %) of the combined optical power, the response periodicity of the UMZI being substantially equal to either N*S or (1/N)*S, where N is an integer and S is a target wavelength spacing of the lasers; and
a photodetector, coupled to a UMZI output;
wherein the heater elements are operated such that each of the lasers is aligned to a corresponding one of a UMZI maximum, minimum, and crossing point.

12. The photonic integrated circuit of claim 11, where x is between 0.01 and 50.

13. The photonic integrated circuit of claim 11,
where the target wavelength spacing S corresponds to a target frequency spacing between 10 GHz and 1600 GHz.

14. The device of claim 1,
wherein the dielectric layer forming the passive waveguide core of the passive waveguide structure comprises at least one of SiN, SiNOₓ, TiO₂, Ta₂O₅, (doped) SiO₂, LiNbO_{3,} Al₂O₃, BaTiO₃ and AlN.

15. The device of claim 1,
wherein the active waveguide structure comprises at least one of InP, GaAs, GaN, a ternary semiconductor involving at least one of In, P, Ga, As, Ga, and N, and a quaternary semiconductor involving at least one of In, P, Ga, As, and N.
